(19) United States
(12) Patent Application Publication
(10) Pub. No.: US 2023/0114395 A1
(43) Pub. Date: Apr. 13, 2023

(54) PHOTODETECTOR AND INTEGRATED CIRCUIT

(71) Applicant: Hon Young Semiconductor Corporation (HYS), Hsinchu (TW)

(72) Inventor: KUANG-HAO CHIANG, New Taipei (TW)

(21) Appl. No.: 17/965,043

(22) Filed: Oct. 13, 2022

(30) Foreign Application Priority Data
Oct. 13, 2021 (CN) 202111190683.8

(51) Int. Cl. H01L 27/146; H01L 31/0352; H01L 31/0336; H01L 31/105; H01L 31/107

(52) U.S. Cl. CPC H01L 27/1461; H01L 31/035218; H01L 31/035263; H01L 31/0336; H01L 31/105; H01L 31/1075

(57) ABSTRACT

A photodetector and an integrated circuit with shortened response time requires a photodetector with an N-type semiconductor layer, a P-type semiconductor layer, and a light absorption layer sandwiched between the N-type semiconductor layer and the P-type semiconductor layer. The light absorption layer includes a layer strained in compression or in tension and a heterostructure which increases the mobility of charge carriers in the light absorption layer.

### FIELD

The subject matter herein generally relates to semiconductors, specifically to a photodetector and an integrated circuit.

### BACKGROUND

A photodetector's response time should be as short as possible. The shorter the response time, the faster the speed of the photodetector in responding. With the development of science and technology, the response speed of current photodetectors needs to be improved.

Therefore, there is room for improvement in the art.

### BRIEF DESCRIPTION OF THE DRAWINGS

Implementations of the present disclosure will now be described, by way of embodiment, with reference to the attached figures.

FIG. 1 is a schematic structural view of a photodetector according to an embodiment of the present disclosure.

FIG. 2 is a graph showing a relationship between sensitivity and wavelength of some photosensitive materials.

FIG. 3 is a schematic structural view of an integrated circuit using the photodetector in FIG. 1 according to an embodiment of the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the exemplary embodiments described herein. However, it will be understood by those of ordinary skill in the art that the exemplary embodiments described herein may be practiced without these specific details. In other instances, methods, procedures, and components have not been described in detail so as not to obscure the related relevant feature being described. Also, the description is not to be considered as limiting the scope of the exemplary embodiments described herein. The drawings are not necessarily to scale, and the proportions of certain parts may be exaggerated to better illustrate details and features of the present disclosure.

The term “comprising” when utilized, means “including, but not necessarily limited to”; it specifically indicates open-ended inclusion or membership in the so-described combination, group, series, and the like. The disclosure is illustrated by way of example and not by way of limitation in the figures of the accompanying drawings in which like references indicate similar elements. It should be noted that references to “an” or “one” embodiment in this disclosure are not necessarily to the same embodiment, and such references can mean “at least one”. The term “circuit” is defined as an integrated circuit (IC) with a plurality of electric elements, such as capacitors, resistors, amplifiers, and the like.

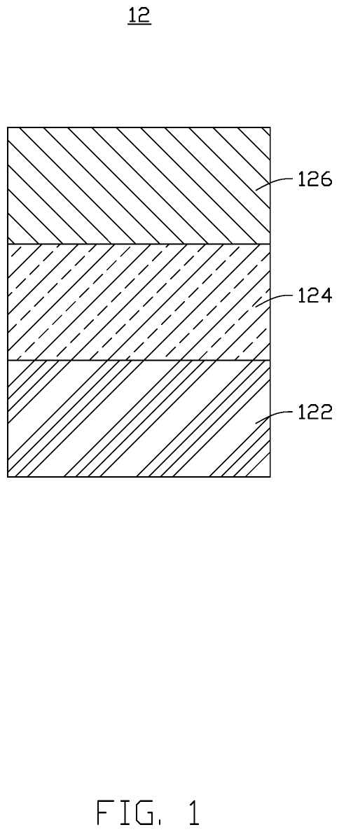

FIG. 1 shows a photodetector 12 according to an embodiment of the present disclosure. The photodetector 12 includes an N-type semiconductor layer 122, a P-type semiconductor layer 126, and a light absorption layer 124. The light absorption layer 124 is between the N-type semiconductor layer 122 and the P-type semiconductor layer 126. The light absorption layer 124 is an intrinsic layer, and the photodetector 12 is a PIN photodiode. The photodetector 12 further includes an N-type contact electrode (not shown) that is in direct contact with and electrically connected to the N-type semiconductor layer 122 and a P-type contact electrode (not shown) that is in direct contact with and electrically connected to the P-type semiconductor layer 126. With a reverse bias voltage applied to the photodetector 12, the photodetector 12 absorbs incident light in a specific wavelength range, and converts the light in the specific wavelength range into an electric current.

Specifically, the photodetector forms a depletion region under the action of reverse bias, and transit time (td) of photogenerated carriers in the depletion region is one of the main factors affecting the response time of the photodetector. The relationship between the transit time (td) of the photogenerated carriers in the depletion region and the mobility (μd) of the carriers can be expressed by formula td=W/vd; vd=μdE, where W is the width of the depletion region, vd is the drift velocity of the carriers s, μd is the mobility of the carriers, and E is the electric field strength in the depletion region.

The transit time (td) of the photogenerated carriers in the depletion region is inversely proportional to the mobility (μd) of the carriers. When the mobility of the carriers is increased the transit time of the photogenerated carriers is reduced, the response time of the photodetector is accordingly reduced, and the response speed of the photodetector is improved.

In the photodetector 12, the light absorption layer 124 includes a strained layer including a heterostructure, and the strain generated in the strained layer increases the mobility of carriers in the light absorption layer 124. This reduces the response time of the photodetector 12, the modulation frequency of the photodetector 12 is accelerated, and the response speed of the photodetector 12 is improved.

In some embodiments, the strained layer is a layer having a compressive strain. The compressive strain generated in the strained layer is configured for increasing the mobility of holes in the light absorption layer 124. For example, the strained layer is in direct contact with the P-type semiconductor layer 126, and a lattice spacing of a material of the P-type semiconductor layer 126 is less than a lattice spacing of a material of the strained layer. The P-type semiconductor layer 126 induces compressive strain in the strained layer, so that the mobility of the holes in the light absorption layer 124 is increased, thereby increasing the response speed of the photodetector 12.

In some other embodiments, the strained layer is a layer having a tensile strain. The tensile strain generated in the strained layer is configured for increasing the mobility of electrons in the light absorption layer 124. For example, the strained layer is in direct contact with the N-type semiconductor layer 122, and a lattice spacing of the material of the N-type semiconductor layer 122 is greater than the lattice spacing of the material of the strained layer. The N-type semiconductor layer 122 induces tensile strain in the strained layer, so that the mobility of electrons in the light absorption layer 124 is increased, thereby increasing the response speed of the photodetector 12.

In some embodiments, the strained layer is a multiple quantum well (MQW) layer, a superlattice layer, or a quantum dots (QDs) layer. The MQW layer and the superlattice layer are both periodic heterostructures made of alternating semiconductors with different bandgaps, each thin alternating material layer containing several or a great many atomic layers. A superlattice is a periodic heterostructure made of alternating materials with different bandgaps. The thickness of each of these periodically alternating material layers is generally about a few nanometers. The band structure that results from such a configuration is a period series of quantum wells.

These non-conductive barriers must be thin enough such that carriers can tunnel through the barrier regions of the multiple wells. A defining property of superlattices is that the barriers between wells are thin enough for adjacent wells to couple. Periodic structures made of repeated quantum wells with barriers that are too thick for adjacent wave functions to couple are called MQW structures. In other words, in superlattices, the potential barriers are thin, or the heights of the potential barriers are low, increasing the probability of electrons in the well tunneling through the potential barrier due to the tunnel effect, and the discrete sub-levels in the potential well form sub-bands with a certain width.

When the barrier thickness (i.e., a thickness of the material with a wider bandgap in the alternating materials with different bandgaps) in a periodic structure made of repeated quantum wells is greater than 20 nm and the barrier height is greater than 0.5 eV, the electrons in multiple wells behave as the sum of the electrons in a single well, this periodic structure is called MQW structure. The quantum well has the potential well of electrons or holes with obvious quantum confinement effect. Generally, quantum well structures with a size below 100 nm in only one dimension can be approximated as a two-dimensional material.

QDs are semiconductor particles only a few nanometers in size, having optical and electronic properties that operate differently from larger particles due to quantum mechanics. QDs are quasi-zero-dimensional nanomaterials composed of a small number of atoms. Generally, a size of the QDs in three dimensions are all below 100 nm, and the appearance of QDs is like a small point-like object. The movement of electrons in QDs is restricted in all directions, so the quantum confinement effect is particularly significant in QDs.

It should be noted that, due to the introduction of strain in the MQW layer, the superlattice layer, or the QDs layer, the energy band structure of the photodetector 12 is changed, enhancing the photon quantum efficiency of the photodetector 12 and expanding the detecting wavelength range of the photodetector 12.

In some embodiments, the N-type semiconductor layer 122 includes N-type silicon (Si); the strained layer includes a silicon/germanium (Si/Ge) heterostructure, a germanium/silicon germanium (Ge/SiGe) heterostructure, a silicon/silicon germanium (Si/SiGe) heterostructure, a heterostructure composing of a group III-V compound semiconductor, a heterostructure composing of a group II-VI compound semiconductor, and a heterostructure composing of the group III-V compound semiconductor and the group II-VI compound semiconductor. The strained layer can be grown epitaxially on the N-type Si.

For example, in one embodiment, the strained layer includes the Si/Ge heterostructure. The Si/Ge heterostructure is epitaxially grown on N-type Si by forming a periodic multi-layer structure of alternating Si layers and Ge layers, each Si layer alternating with one Ge layer. In another embodiment, the strained layer includes the Ge/SiGe heterostructure. The Ge/SiGe heterostructure is epitaxially grown on the N-type Si by forming a periodic multi-layer structure of alternating Ge layers and the SiGe layers, each Ge layer alternating with one SiGe layer. Similarly, the Si/SiGe heterostructure included in the strained layer can be epitaxially grown on N-type Si by forming a periodic multi-layer structure of alternating Si layers and SiGe layers, each Si layer alternating with one SiGe layer. Additionally, the group III-V compound semiconductor of the heterostructure can be, for example, GaAs, InGaAs, InP, GaN, etc., which can also be epitaxially grown on N-type Si. The group II-VI compound semiconductor can be, for example, CdTe.

In some embodiments, the P-type semiconductor layer 126 includes a P-type silicon germanium (SiGe) layer. The P-type SiGe layer is gradient-doped, or different locations of the P-type SiGe layer have different silicon-germanium (Si—Ge) ratios.

For example, in some embodiments, the doping concentration of Ge in the P-type SiGe layer is least at the location which is in contact with the strained layer, and gradually increases along a thickness direction of the P-type SiGe layer.

In some embodiments, the doping concentration of Ge in the P-type SiGe layer is greatest at the location in contact with the strained layer, and gradually increases along the thickness direction of the P-type SiGe layer.

In some embodiments, the doping concentration of Ge in the P-type SiGe layer first increases and then decreases along the thickness direction of the P-type SiGe layer.

In some embodiments, different locations of the P-type SiGe layer may have different SiGe ratios to improve device performance. In other embodiments, the doping concentration of Ge in the P-type SiGe layer may be fixed and constant, and the SiGe ratio in the P-type SiGe layer is fixed and constant.

In some embodiments, the strained layer is a Ge/SiGe heterostructure or a Si/SiGe heterostructure, and the photodetector 12 is sensitive from 400 nm to 1600 nm. In other words, a working wavelength range (i.e., a detectable wavelength range of light) of the photodetector 12 is from 400 nm to 1600 nm.

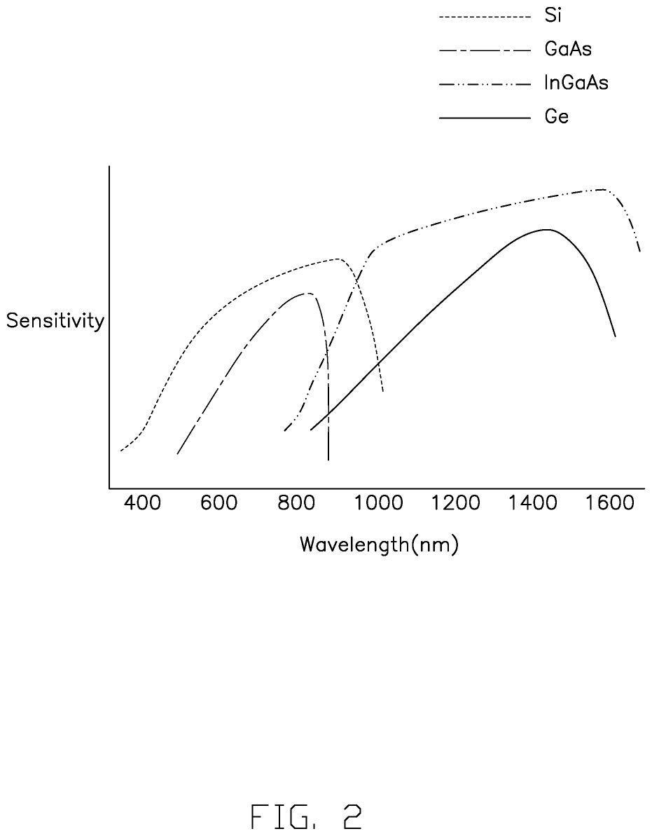

Since the band gap of Si is 1.12 eV, the detectable wavelength range of traditional Si-based photodetectors is from 400 nm to 1100 nm, as shown in FIG. 2. The forbidden bandwidth of Ge is 0.67 eV, which the detectable wavelength range of traditional Ge-based photodetectors ranges from 800 nm to 1600 nm, as shown in FIG. 2. In the photodetector 12 in which the strained layer is a Ge/SiGe heterostructure or a Si/SiGe heterostructure, the detectable wavelength is controlled and expanded by adjusting the composition ratio of SiGe, so that a working wavelength range of the photodetector 12 is from 400 nm to 1600 nm, and infrared light waves greater than 1100 nm can be detected.

In some embodiments, the photodetector 12 is a PIN photodiode or an avalanche diode. The light absorption layer 124 serves as an intrinsic layer (I-type layer) of the PIN photodiode or the avalanche diode. When the photodetector 12 is an avalanche diode, the photodetector 12 further includes an avalanche region, to utilize the avalanche multiplication effect of carriers to amplify the photoelectric signal, to improve sensitivity of detection.

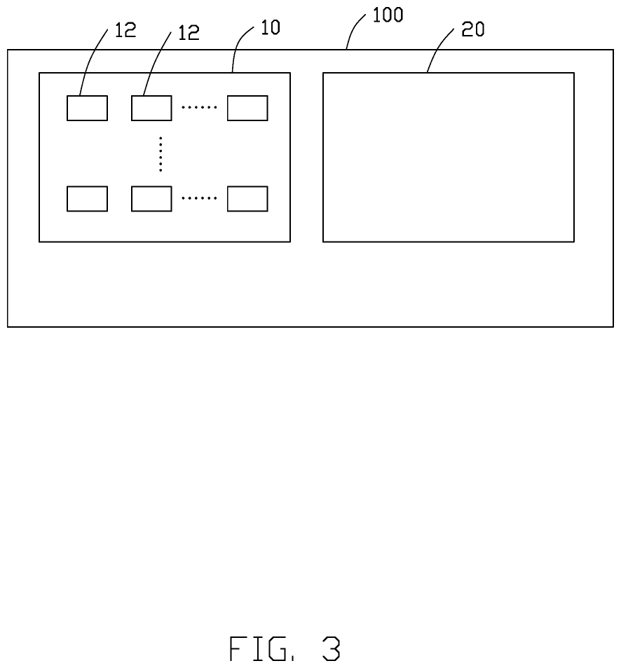

In some embodiments, an integrated circuit 100 is provided. As shown in FIG. 3, the integrated circuit 100 includes an image sensor 10 and other electronic components 20. The image sensor 10 includes a plurality of the photodetectors 12. Each photodetector 12 serves as a photosensitive element of the image sensor 10, to convert optical signals into electrical signals. Since the integrated circuit 100 includes the photodetectors 12, the integrated circuit 100 also has a high processing speed. The integrated circuit 100 may have a 3D package structure. The image sensor 10 may be a front side illumination (FSI) image sensor or a back side illumination (BSI) image sensor. Other electronic components 20 may be thin film transistors, resistors, capacitors, and the like.

It is to be understood, even though information and advantages of the present exemplary embodiments have been set forth in the foregoing description, together with details of the structures and functions of the present exemplary embodiments, the disclosure is illustrative only. Changes may be made in detail, especially in matters of shape, size, and arrangement of parts within the principles of the present exemplary embodiments to the full extent indicated by the plain meaning of the terms in which the appended claims are expressed.

What is claimed is:

1. A photodetector comprising:
an N-type semiconductor layer;
a P-type semiconductor layer; and
a light absorption layer between the N-type semiconductor layer and the P-type semiconductor layer, wherein the light absorption layer comprises a strained layer comprising a heterostructure.

2. The photodetector of claim 1, wherein the strained layer is a layer having a compressive strain.

3. The photodetector of claim 2, wherein the strained layer is in direct contact with the P-type semiconductor layer, and a lattice spacing of a material of the P-type semiconductor layer is less than a lattice spacing of a material of the strained layer.

4. The photodetector of claim 1, wherein the strained layer is a layer having a tensile strain.

5. The photodetector of claim 4, wherein the strained layer is in direct contact with the N-type semiconductor layer, and a lattice spacing of the material of the N-type semiconductor layer is greater than a lattice spacing of a material of the strained layer.

6. The photodetector of claim 1, wherein the strained layer is a multiple quantum well layer, a superlattice layer or a quantum dot layer.

7. The photodetector of claim 6, wherein the N-type semiconductor layer comprises N-type silicon (Si), and the strained layer comprises at least one of a silicon/germanium (Si/Ge) heterostructure, a germanium/silicon germanium (Ge/SiGe) heterostructure, a silicon/silicon germanium (Si/SiGe) heterostructure, a heterostructure composing of a group III-V compound semiconductor, a heterostructure composing of a group II-VI compound semiconductor, and a heterostructure composing of the group III-V compound semiconductor and the group II-VI compound semiconductor.

8. The photodetector of claim 7, wherein the P-type semiconductor layer comprises a P-type silicon germanium (SiGe) layer.

9. The photodetector of claim 8, wherein the P-type SiGe layer is gradient-doped, or different locations of the P-type SiGe layer have different silicon-germanium ratios.

10. The photodetector of claim 7, wherein the strained layer is a Ge/SiGe heterostructure or a Si/SiGe heterostructure, and the photodetector is sensitive from 400 nm to 1600 nm.

11. The photodetector of claim 1, wherein the photodetector is a PIN photodiode or an avalanche photodiode.

12. An integrated circuit comprising an image sensor, the image sensor comprising a plurality of photodetectors, each of the plurality of photodetectors comprising:
an N-type semiconductor layer;
a P-type semiconductor layer; and
a light absorption layer between the N-type semiconductor layer and the P-type semiconductor layer, wherein the light absorption layer comprises a strained layer comprising a heterostructure.

13. The integrated circuit of claim 12, wherein the strained layer is a layer having a compressive strain, the strained layer is in direct contact with the P-type semiconductor layer, and a lattice spacing of a material of the P-type semiconductor layer is less than a lattice spacing of a material of the strained layer.

14. The integrated circuit of claim 12, wherein the strained layer is a layer having a tensile strain, the strained layer is in direct contact with the N-type semiconductor layer, and a lattice spacing of the material of the N-type semiconductor layer is greater than a lattice spacing of a material of the strained layer.

15. The integrated circuit of claim 12, wherein the strained layer is a multiple quantum well layer, a superlattice layer or a quantum dot layer.

16. The integrated circuit of claim 15, wherein the N-type semiconductor layer comprises N-type silicon (Si), and the strained layer comprises at least one of a silicon/germanium (Si/Ge) heterostructure, a germanium/silicon germanium (Ge/SiGe) heterostructure, a silicon/silicon germanium (Si/SiGe) heterostructure, a heterostructure composing of a group III-V compound semiconductor, a heterostructure composing of a group II-VI compound semiconductor, and a heterostructure composing of the group III-V compound semiconductor and the group II-VI compound semiconductor.

17. The integrated circuit of claim 16, wherein the P-type semiconductor layer comprises a P-type silicon germanium (SiGe) layer.

18. The integrated circuit of claim 17, wherein the P-type SiGe layer is gradient-doped, or different locations of the P-type SiGe layer have different silicon-germanium ratios.

19. The integrated circuit of claim 15, wherein the strained layer is a Ge/SiGe heterostructure or a Si/SiGe heterostructure, and the photodetector is sensitive from 400 nm to 1600 nm.

20. The integrated circuit of claim 12, wherein the photodetector is a PIN photodiode or an avalanche photodiode.
